(19) United States
(12) Patent Application Publication
(10) Pub. No.: US 2019/0033500 A1
(43) Pub. Date: Jan. 31, 2019

(54) PACKAGE-INTEGRATED PIEZOELECTRIC OPTICAL GRATING SWITCH ARRAY

(71) Applicant: Intel Corporation, Santa Clara, CA (US)

(72) Inventors: Thomas L. SOUNART, Chandler, AZ (US); Baris BICEN, Chandler, AZ (US); Feras EID, Chandler, AZ (US); Sasha N. OSTER, Marion, IA (US); Aleksandar ALEKSOV, Chandler, AZ (US); Shawna M. LIFF, Scottsdale, AZ (US); Valluri R. RAO, Saratoga, CA (US); Johanna M. SWAN, Scottsdale, AZ (US)

(21) Appl. No.: 16/072,173

(22) PCT Filed: Apr. 1, 2016
(86) PCT No.: PCT/US2016/025728

§ 371 Date: Jul. 23, 2018

(51) Int. Cl. G02B 5/18; G02B 26/08; H01L 41/09

(52) U.S. Cl. CPC G02B 5/1861; H01L 41/09; G02B 26/0816; G02B 26/0808

(57) ABSTRACT

Embodiments of the invention include an optical grating switch integrated into an organic substrate and methods of forming such devices. According to an embodiment, the optical grating switch may include a cavity formed into an organic substrate. Additionally, the optical grating switch may include an array of moveable beams anchored to the organic substrate and suspended over the cavity. In an embodiment of the invention, each of the moveable beams in the optical grating switch may include a piezoelectric region formed over end portions of the moveable beam and a top electrode formed over a top surface of each of the piezoelectric regions. In order to reflect or diffract light, embodiments of the invention may include moveable beams that include a reflective surface formed over a central portion of the moveable beam.

### FIELD OF THE INVENTION

Embodiments of the present invention relate generally to the manufacture of optical grating switches (OGSs). In particular, embodiments of the present invention relate to OGSs that are integrated into organic substrates and are actuated with piezoelectric materials and methods for manufacturing such devices.

### BACKGROUND OF THE INVENTION

Optical switches or valves are used to control images in displays/projectors, maskless lithography, and computer-to-plate (CTP) printing. An optical or light switch modulates light off or on to a microscale target such as a pixel in a display. Some examples of optical switch technologies include liquid crystal displays (LCDs), digital micromirror devices (DMDs), and optical grating switches (OGSs). From this group of optical switch technologies, OGSs have been shown to be superior devices for many applications due to fast switching speeds, high contrast ratios, high optical efficiencies, and high reliabilities. For example, the OGS switching speed is typically orders of magnitude faster than the switching speed of DMDs and LCDs (e.g., OGSs may have a switching time that is in the tens of nanoseconds). This simplifies drive electronics and memory requirements and enables a greater range of color variation and shades of grey. The superior reliability results from the simple/robust operation that includes no moving parts that are in contact with each other and the small deflections that are needed to form a diffraction grating (e.g., approximately 200 nm). Optical efficiency is also very high (e.g., about an order of magnitude higher than LCDs) due to a large fraction of the light being diffracted to the 1^{st} order direction, as opposed to LCD devices that absorb a significant portion of the light.

Despite the superior performance attributes compared to other optical switch technologies, OGSs have not been widely adopted for several reasons. One reason is that the OGSs are typically driven by electrostatic actuation. Electrostatic actuation has design limitations due to a pull-in instability and requires relatively high voltages. Additionally, OGSs are currently fabricated on silicon wafers. Silicon-based OGSs suffer significant drawbacks. One drawback is that silicon substrates and the processing operations used to form silicon-based OGSs are relatively expensive, compared to other electronics fabrication materials and processes, such as organic substrates used for packaging or board manufacturing. Additionally, silicon-based OGSs are often fabricated at wafer level. Therefore, fabrication of OGSs on silicon cannot take advantage of scaling to larger substrates due to the limitation on wafer sizes (e.g., 4″ or 6″). Furthermore, after silicon-based OGSs are fabricated, they still need to be packaged and then assembled into their final system. Accordingly, silicon-based OGSs that are currently available suffer from high cost, assembly challenges, and increased overall size due to additional packaging required.

One proposal to overcome the difficulties associated with electrostatic actuation of OGSs is to use piezoelectric actuation instead. Piezoelectric actuation requires less voltage than electrostatic actuation and eliminates the issue of pull-in instability. However, when piezoelectrically actuated OGSs are used, it is not currently possibly to replace semiconductor fabrication with low-temperature materials, such as organic substrates. Piezoelectric systems are limited to being formed on high-temperature compatible substrates because an annealing process is needed to crystallize the piezoelectric layer. Typically, the annealing temperatures are in excess of 500° C. As such, low-temperature substrates, such as organic substrates, cannot currently be used to form piezoelectric systems because the elevated temperatures may melt or otherwise damage the substrate.

### BRIEF DESCRIPTION OF THE DRAWINGS

FIG. 1A is a cross-sectional illustration of an optical grating switch in an unactuated state, according to an embodiment of the invention.

FIG. 1B is a cross-sectional illustration of an optical grating switch in an actuated state, according to an embodiment of the invention.

FIG. 2A is a plan view of an optical grating switch integrated into an organic substrate, according to an embodiment of the invention.

FIG. 2B is a cross-sectional illustration of a moveable beam in an optical grating switch array that is integrated into an organic substrate, according to an embodiment of the invention.

FIG. 3 is a cross-sectional illustration of a moveable beam in an optical grating switch array that is integrated into an organic substrate and also includes an insulation layer over the moveable beam, according to an additional embodiment of the invention.

FIG. 4 is a plan view of an optical grating switch integrated with moveable and static beams formed in an alternating pattern, according to an embodiment of the invention.

FIG. 5 is a plan view of an array of optical grating switches formed on an organic surface and controlled by an integrated circuit die, according to an embodiment of the invention.

FIG. 6 is a schematic of a ray diagram of an optical grating switch reflecting a light source onto a screen, according to an embodiment of the invention.

FIG. 7A is a cross-sectional illustration of a substrate after a beam is formed over the top surface of the substrate, according to an embodiment of the invention.

FIG. 7B is a cross-sectional illustration of the substrate after piezoelectric regions are formed over end portions of the beam, according to an embodiment of the invention.

FIG. 7C is a cross-sectional illustration of the substrate after a second electrode is formed over a top surface of the piezoelectric regions, according to an embodiment of the invention.

FIG. 7D is a cross-sectional illustration of the substrate after a reflective surface is formed over the beam, according to an embodiment of the invention.

FIG. 7E is a cross-sectional illustration of the substrate after a cavity is formed below the beam in order to allow for the beam to deflect towards the substrate when a voltage is applied across the piezoelectric regions, according to an embodiment of the invention.

FIG. 8 is a cross-sectional illustration of a piezoelectric layer being formed over an electrode with an insulating layer formed over the beam and the electrode formed over a top surface of the insulating layer, according to an embodiment of the invention.

FIG. 9 is a schematic of a computing device built in accordance with an embodiment of the invention.

### DETAILED DESCRIPTION OF THE INVENTION

Described herein are systems that include an optical grating switch (OGS) that includes piezoelectrically actuated moveable beams formed on an organic substrate and methods of forming such devices. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Embodiments of the invention include fabricating a piezoelectrically actuated OGS as part of a package substrate using panel-level organic package manufacturing processes. Previously, piezoelectric components needed to be manufactured on substrates that can withstand high temperatures, such as silicon substrates. High temperature compatible substrates such as these were used because the piezoelectric material needed to be annealed at temperatures greater than approximately 500° C. in order to crystallize. However, embodiments of the present invention allow for piezoelectric material to be deposited and crystallized at much lower temperatures by using a pulsed laser annealing process, described in greater detail below. Therefore, piezoelectrically actuated OGSs are able to be fabricated on low temperature organic substrates that are typically used in package and board manufacturing.

Manufacturing OGSs with piezoelectrically actuated moveable beams on organic substrates allows for a decrease in the manufacturing cost. For example, technologies and materials developed for package/board processing are significantly less expensive than technologies and materials used for semiconductor processing. Fabricating the moveable beams directly in the substrate or board reduces the cost over silicon-based OGSs because of the large panels (e.g., 510 mm×515 mm) used for organic substrate and board fabrication, the less expensive processing operations, and the less expensive materials used in those systems compared to silicon. In addition, since the moveable beams of the OGSs are directly manufactured as part of the package substrate or board, they do not require an additional assembly operation. Also, by using piezoelectric actuation, lower actuation voltages are required compared to the electrostatic approach, and the pull-in electrostatic instability problem is eliminated. Additionally, the overall thickness is small (e.g., in the tens of micrometers) since additional packaging needed for silicon-based OGSs is not required. This also enables integration in electronic packages to meet size constraints in applications such as mobile device displays.

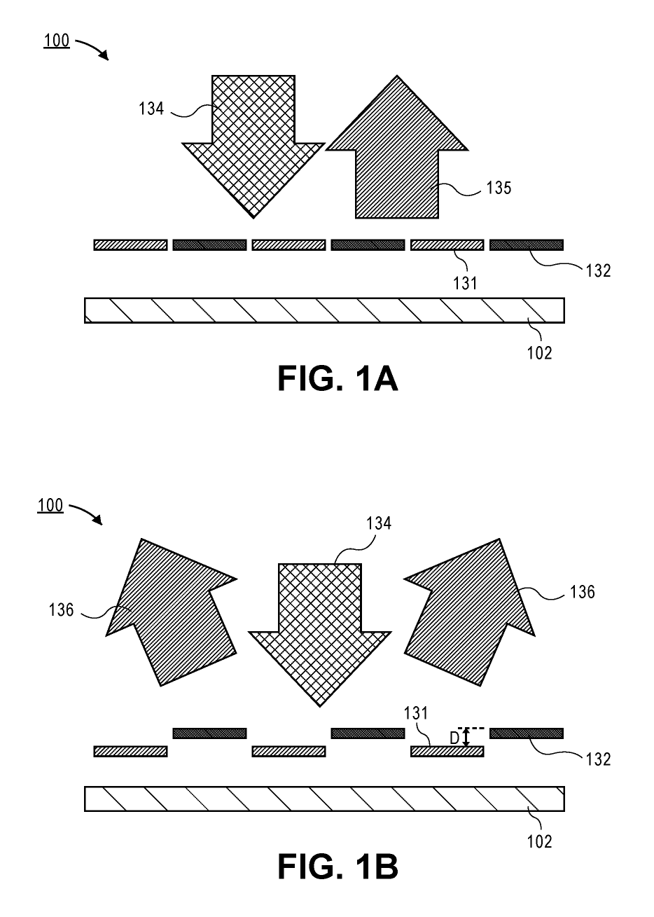

Referring now to FIGS. 1A and 1B, a schematic of an OGS 100 is shown to illustrate how an OGS may function in the off state (FIG. 1A) and the on state (FIG. 1B), according to an embodiment of the invention. In the illustrated embodiment, a series of reflective mirrors 131 and 132 are formed in an alternating pattern over a substrate 102. According to an embodiment, the mirrors 131 are the actuating mirrors and are able to be displaced towards the substrate 102. In the off-state illustrated in FIG. 1A, the top surfaces of the mirrors 131 and 132 are held at substantially the same height. Accordingly, when an incoming light 134 is directed at the OGS 100, the mirrors 131 and 132 function as a single mirror and substantially all of the incident light 134 is reflected as 135 at the same angle the light hit the mirrors 131 and 132.

Referring now to FIG. 1B, the OGS is in the on state, and the actuating mirrors 131 are displaced towards the substrate 102 by a distance D. The alternating pattern of the mirrors 131 and 132 causes the incident light 134 to diffract due to constructive and destructive interference between light reflecting from the mirrors 131 and 132. Accordingly, a substantial portion (up to approximately 81% when the distance D is equal to approximately one-quarter of the wavelength of the incident light 134) of the incident light 134 is diffracted to the first order (i.e., approximately ±6°), as illustrated by arrows 136. Accordingly, a spatial filter may be configured to block light from the zero order and allow light from the first order to pass (or vice versa), as will be described in greater detail below.

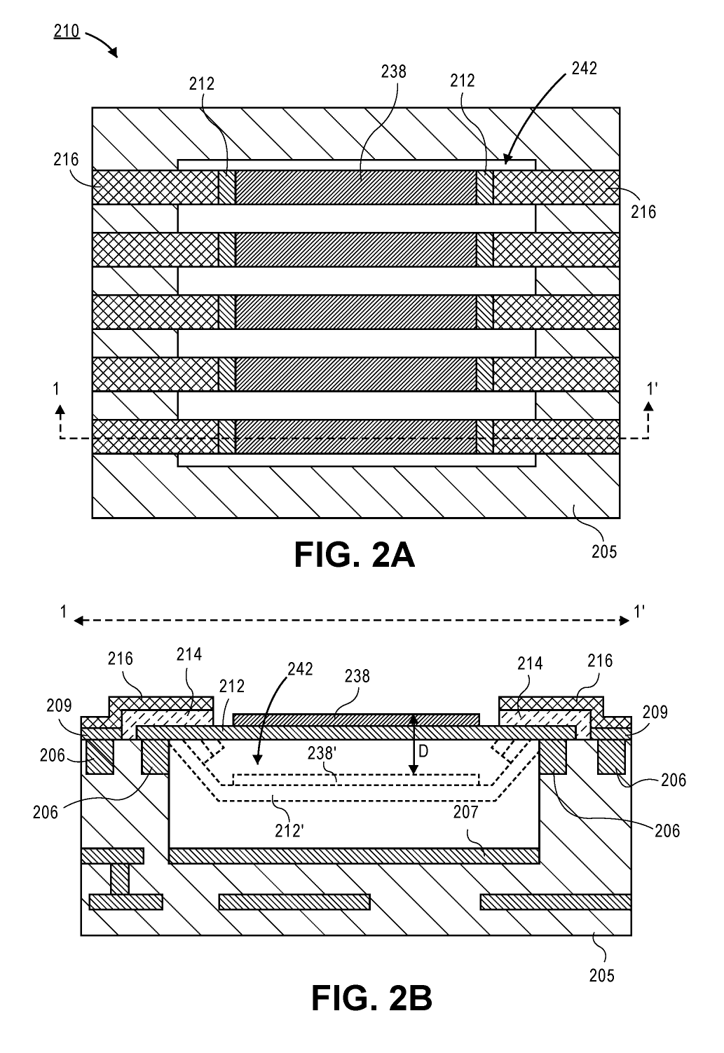

Referring now to FIGS. 2A and 2B, a plan view illustration and a corresponding cross-sectional illustration along line 1-1′ of an OGS 210 that is integrated into an organic substrate 205 is shown, according to an embodiment of the invention. In an embodiment, the organic substrate 205 may be any suitable organic material. By way of example, the organic substrate 205 may be a polymer material, such as, for example, polyimide, epoxy, or build-up film. The organic substrate 205 may include one or more layers (i.e., build-up layers). According to an embodiment, the organic substrate 205 may also include one or more conductive traces 207, vias 206, and pads 209 (visible in FIG. 2B) to provide electrical routing in the organic substrate 205. The conductive traces 207, vias 206, and pads 209 may be any suitable conductive material typically used in organic packaging applications (e.g., copper, tin, aluminum, alloys of conductive materials, and may also include multiple layers, such as seed layers, barrier layers, or the like).

According to an embodiment, a plurality of moveable beams 212 are suspended across a cavity 242. In the plan view in FIG. 2A only a portion of the moveable beams 212 are shown and the remainder is obscured by the reflective surface 238 and the top electrode 216. FIG. 2B more clearly illustrates the entire length of the moveable beam 212 spanning across the cavity 242. Referring back to FIG. 2A, the plan view illustrates reflective surfaces 238 formed substantially in the middle portion of each moveable beam 212. As such, displacing the moveable beam allows for the reflective surface 238 to be displaced as well. Accordingly, when alternating moveable beams 212 are displaced towards the substrate 205, a diffraction grating is formed, similar to the diffraction grating described above with respect to FIG. 1B.

According to an embodiment, the combined surface area of all of the reflective surfaces 238 may be sized to capture incident light that will be reflected or diffracted by the OGS 210. For example, the surface area of each of the reflective surfaces 238 may be between approximately 1 μm-50 μm in width by 10 μm-1000 μm in length, though OGSs 210 may have reflective surfaces 238 with smaller or larger surface areas, according to embodiments of the invention. According to an embodiment, the gap between reflective surfaces 238 may be between approximately 0.5 μm and 10 μm.

According to an embodiment, the reflective surface 238 may have a surface roughness that is less than approximately 300 nm. Additional embodiments may include reflective surfaces 238 that have a surface roughness that is less than approximately 100 nm. Yet another embodiment may have a surface roughness that is less than approximately 10 nm. The surface roughness may be dictated by the deposition techniques used to form the reflective surface 238. Additionally, surface treatments may be used to further reduce the surface roughness of the reflective surface 238. According to an embodiment, the reflective surface 238 may be any reflective material. For example, the reflective surface 238 may be aluminum, silver, gold, tin, alloys of reflective materials, or the like. Additional embodiments may include choosing the material or surface treatment of the reflective surface 238 to provide wavelength selective effects. For example, gold may be used to filter out wavelengths (e.g., the wavelengths approximately 550 nm or less). According to an embodiment, a protective coating (not shown) may be formed over the reflective surface 238 to prevent oxidation or other damage. For example, the protective coating may be any optically clear material.

In the illustrated embodiment, the OGS 210 includes five moveable beams 212 with reflective surfaces 238, though embodiments of the invention are not limited to such configurations. For example, as few as two moveable beams 212 with reflective surfaces 238 may be used to produce a diffraction grating in the OGS 210. However, reducing the number of moveable beams 212 and reflective surfaces 238 may decrease the percentage of incident light that is diffracted to the first order. Accordingly, some embodiments of the invention include four or more moveable beams 212 in order to provide the desired diffraction efficiency.

Returning now to FIG. 2B, the piezoelectric actuation mechanism is shown in greater detail. As noted above, each end of the moveable beam 212 may be anchored to the substrate 205 and/or a conductive via 206, pad 209, or trace 207. Since a central portion of the moveable beam 212 is not supported from below, the central portion of the moveable beam 212 may be displaced towards the substrate. According to an embodiment, each moveable beam 212 may be displaced by a piezoelectric stack that includes piezoelectric material 214 formed between two electrodes on each end of the moveable beam 212. In the illustrated embodiment the piezoelectric material 214 is formed directly on the moveable beam 212 and the moveable beam 212 functions as the bottom electrode. According to an embodiment, a top electrode 216 may be formed over a top surface of the piezoelectric material 214.

According to an embodiment, the moveable beam 212 and the top electrode 216 are formed with a conductive material. In some embodiments, the moveable beam 212 and the top electrode 216 may be formed with the same conductive material used to form the conductive traces 207, vias 206, and pads 209 formed in the organic substrate 205. Such an embodiment allows for the manufacturing of the microelectronic package to be simplified since additional materials are not needed, though embodiments are not limited to such configurations. For example, the top electrode 216 and the moveable beam 212 may be different materials than the traces 207. Additional embodiments may include a moveable beam 212 that is a different material than the top electrode 216. The conductive material used for the moveable beam 212 and the top electrode 216 may be any conductive material (e.g., copper, aluminum, alloys, etc.).

High performance piezoelectric materials typically require a high temperature anneal (e.g., greater than 500° C.) in order to attain the proper crystal structure to provide the piezoelectric effect. As such, previous piezoelectrically actuated OGSs, such as those described above, require a substrate that is capable of withstanding high temperatures (e.g., silicon). Organic substrates, such as those described herein, typically cannot withstand temperatures above 260° C. However, embodiments of the present invention allow for a high performance piezoelectric layer 214 to be formed at much lower temperatures. For example, instead of a high temperature anneal, embodiments include depositing the piezoelectric layer 214 in an amorphous phase and then using a pulsed laser to crystallize the piezoelectric layer 214. The pulsed laser may provide sufficient energy to the piezoelectric layer to drive crystallization without significantly increasing the temperature of the substrate or heating it to temperatures that may cause substrate degredation. According to an embodiment, a pulsed laser annealing process used to crystallize the amorphous piezoelectric layer may use a laser source (e.g., an excimer laser) with an pulse energy density in the range of approximately 10-100 mJ/cm² and pulse width in the range of approximately 10-50 nanoseconds. In an embodiment, the piezoelectric layer 214 may be deposited with a sputtering process, a chemical solution deposition process, an ink jetting process, or the like. According to an embodiment, the piezoelectric layer may be lead zirconate titanate (PZT), potassium sodium niobate (KNN), zinc oxide (ZnO), or combinations thereof.

The moveable beam 212 may be displaced by applying a voltage across the moveable beam 212 and the top electrode 216. The voltage produces strain in the piezoelectric layer 214 that causes the moveable beam 212 to displace into the cavity 242 towards substrate 205, as illustrated by the dashed outlines of the moveable beam 212′ and the reflective surface 238′.

As illustrated in FIG. 2B, the moveable beam 212 is displaced towards the substrate 205 a distance D. The distance D may be proportional to the voltage applied across the piezoelectric regions 214. In an embodiment, the distance D may be chosen so that D is substantially equal to approximately one-quarter of the wavelength of incident light in order to provide maximum diffraction efficiency. However, embodiments of the invention are not limited to digital responses. Instead, the moveable beam 212 may be displaced in an analog manner to any distance. Displacing alternating moveable beams 212 a distance other than one-quarter the wavelength may provide different effects to the light (e.g., gray-scaling) that may be desirable in display technologies to provide a broader range of colors.

In some embodiments, uniform displacement across multiple moveable beams 212 in the array of moveable beams in the OGS 210 may be obtained by electrically connecting moveable beams 212 in parallel. For example, in FIG. 2A the first, third, and fifth moveable beams 212 (counting from top to bottom) may be electrically connected to each other in parallel, and the second and fourth moveable beams (counting from top to bottom) may be connected to each other in parallel. Alternative embodiments may also provide an array of moveable beams 212 that are each individually addressable.

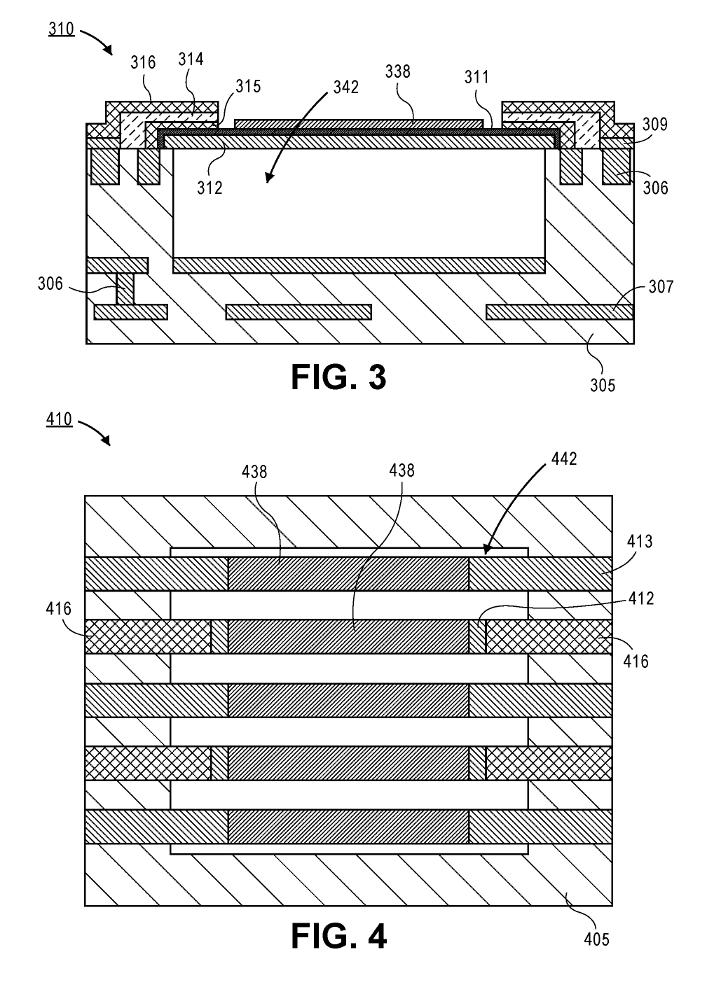

Referring now to FIG. 3, a cross-sectional illustration of an OGS 310 is shown, according to an additional embodiment of the invention. The OGS 310 in FIG. 3 is substantially similar to the OGS 210 illustrated in FIG. 2B, with the exception that the moveable beam 312 is not used as an electrode. According to an embodiment, the moveable beam 312 may be electrically isolated from the piezoelectric regions 314 and the electrodes by an electrically insulating layer 311. The electrically insulating layer 311 may be any suitable non-conductive material. For example, the insulating layer 311 may be an inorganic insulator, such as a nitride or an oxide (e.g., silicon nitride (SiN) or silicon oxide (SiO₂)).

In order to generate strain in the piezoelectric region 314, a bottom electrode 315 may be formed in contact with the piezoelectric region 314. The bottom electrode 315 may be formed directly over the insulating layer 311, or it may be formed over other layers (e.g., adhesion or buffer layers) that are formed over the insulating layer 311. Additionally, the electrode 315 may be electrically coupled to a conductive via 306, trace 307, or pad 309 on the organic substrate 305. As such, a voltage may be applied across the piezoelectric region 314 to cause displacement of the moveable beam 312.

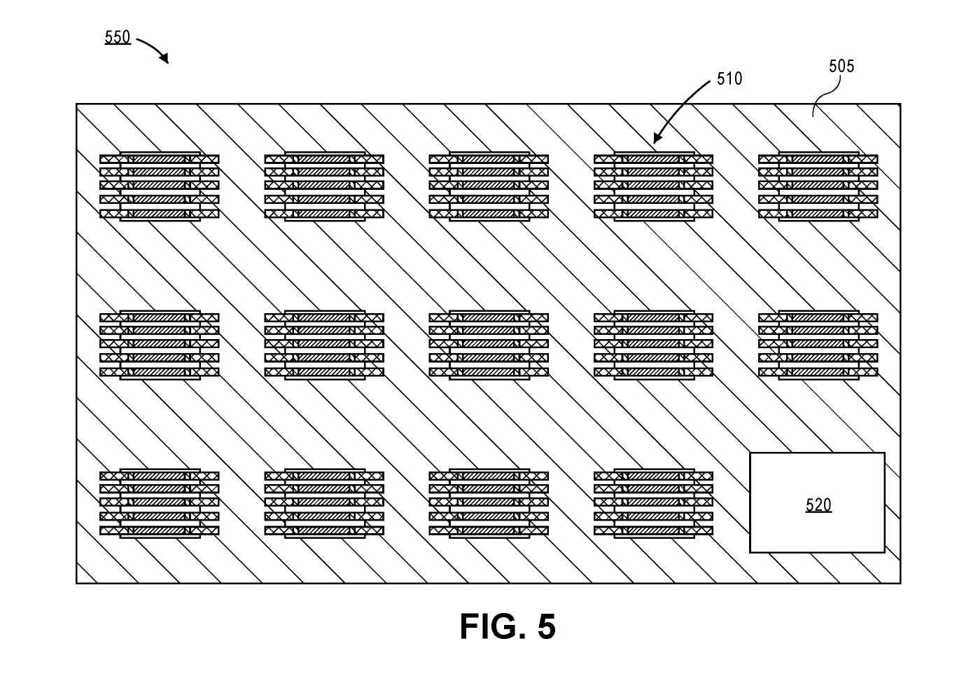

Referring now to FIG. 4, a plan view illustration of an OGS 410 is shown, according to an additional embodiment of the invention. The OGS 410 in FIG. 4 is substantially similar to the OGS 210 illustrated in FIG. 2A, with the exception that three of the moveable beams 412 have been replaced with static beams 413. According to an embodiment, the static beams 413 are substantially similar to the moveable beams 412, except that they do not include a piezoelectric stack, and therefore, are not able to be displaced. However, since the grating pattern is formed by displacing only alternating reflective surfaces 438, not every reflective surface 438 needs to be displaceable. Accordingly, the electrical routing may be decreased since voltage may not need to be applied to all of the beams in the OGS 410.

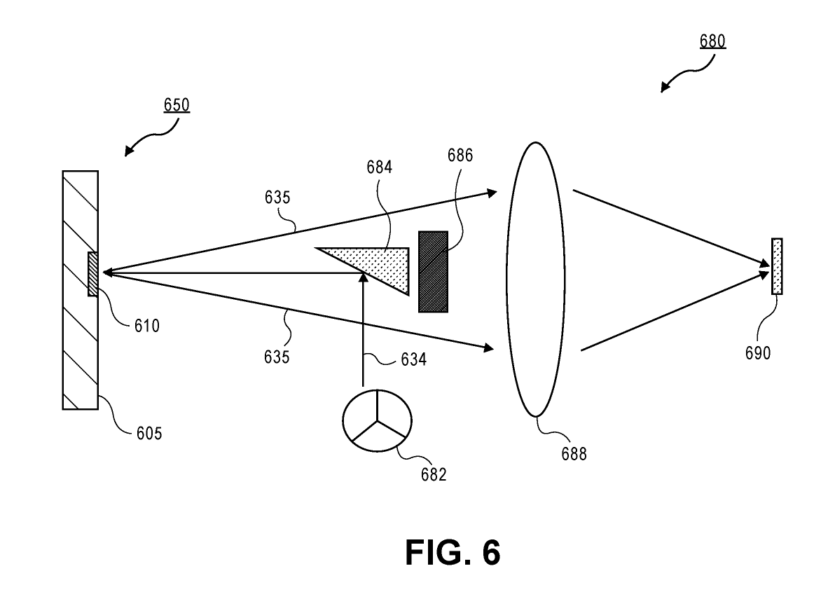

Referring now to FIG. 5, a plan view of a portion of a display system 550 is shown, according to an embodiment of the invention. As illustrated, a plurality of OGSs 510 may be formed across a surface of an organic substrate 505. While fourteen different OGSs 510 are shown on the organic substrate 505, it is to be appreciated that as few as one or even thousands, or more OGSs 510 may be formed on an organic substrate 505. According to an embodiment, an integrated circuit die 520, such as a processor, may control the switching of each OGS 510 on the organic substrate. For example, the top and bottom electrodes of each movable beam may be electrically coupled to the integrated circuit die by traces, vias, and/or pads formed on or in the organic substrate (not visible in FIG. 5). As such, the integrated circuit die 550 may provide a voltage to each piezoelectric region in order to drive deflection of the moveable beams.

In some embodiments, each of the OGSs 510 on the organic substrate 505 may be used to control one or more pixels on a display. In the standard red-green-blue (RGB) pixel configuration, a red light source, a green light source, and a blue light source may each provide incident light to a single OGS 510. Since OGSs 510 are capable of high switching speeds (e.g., switching time of tens of nanoseconds), each color may be switched on and off by the OGS 510 to provide the desired mix of color perceived by a human. Alternatively, embodiments may include an OGS 510 dedicated to each color for every pixel.

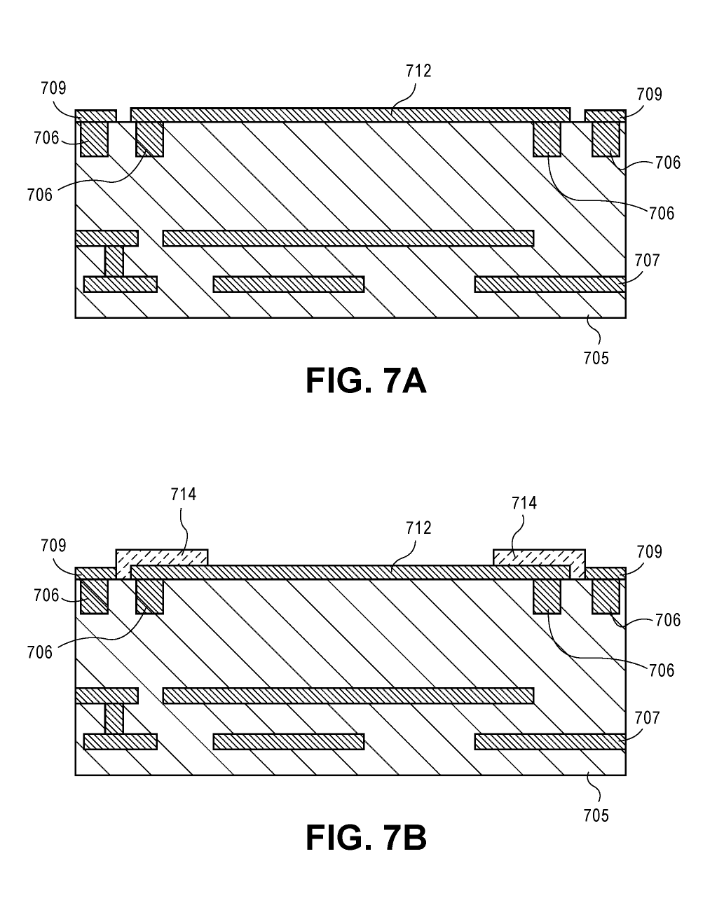

Referring now to FIG. 6, a schematic of a ray diagram illustrates a display system 650 with an OGS 610 in an actuated state and optical components 680 for directing incident light 634 to the OGS 610 and focusing the diffracted light 635 onto a screen 690. According to an embodiment, the incident light 634 may be produced by any suitable light source 682. For example, the light source 682 may be a light emitting diode (LED), a laser, or any other light source. In some embodiments, the light source 682 may include multiple light sources (e.g., a color wheel). Embodiments of the invention may include a mirror 684 or any other optical device for directing the incident light 634 from the light source 682 to the OGS 610. When the OGS 610 is actuated, diffracted light 635 is able to pass through a spatial filter 686 that is configured to block reflected light (i.e., light reflected when the OGS 610 is not actuated). According to an embodiment, a lens 688 may focus the diffracted light 635 to a location (e.g., a pixel) on the screen.

According to an embodiment, a plurality of OGSs 610 may be formed on the organic substrate 605, and each OGS 610 may be responsible for projecting a single pixel onto the screen. According to an additional embodiment of the invention, the optical components 680 may allow for scanning, and each OGS 610 may be responsible for projecting more than a single pixel on the screen 690. Furthermore, due to the fast switching speed of OGSs 610, some embodiments of the invention may allow for a single OGS 610 to be scanned in the X and Y directions in order to provide all of the pixels on a screen 690. While FIG. 6 is described with respect to display systems, it is to be appreciated that embodiments of the invention may utilize substantially similar concepts and configurations to allow for many different applications, such as, but not limited to, telecommunications (e.g., optical switching), spectrometers, adaptive optics, optical precision metrology, maskless lithography, and CTP printing.

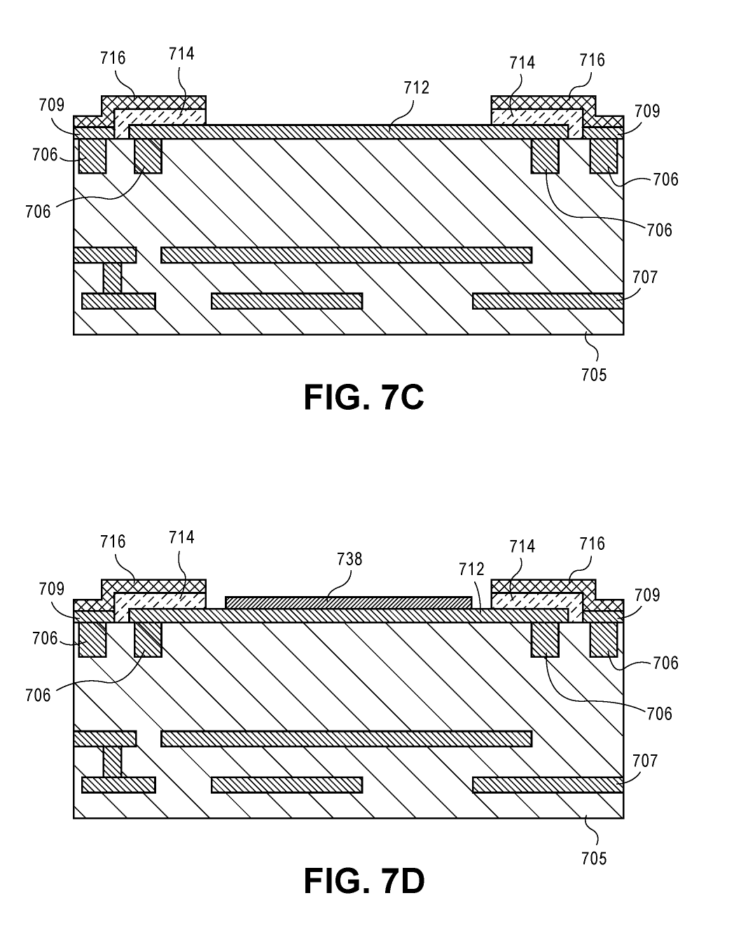

Referring now to FIGS. 7A-7E, a process flow for forming a moveable beam for use in a OGS that is integrated on an organic substrate is shown, according to an embodiment of the invention. While the cross-sectional views illustrate the fabrication of a single moveable beam, it is to be appreciated that a plurality of moveable beams may be manufactured in parallel to form an OGS, and a plurality of OGSs may also be formed in parallel on a single organic substrate. Referring now to FIG. 7A, the structure that will form the moveable beam 712 is formed over a top surface of a substrate 705. According to an embodiment, the moveable beam 712 may be formed with manufacturing processes known in the semiconductor and substrate manufacturing industries, such as semi-additive processing, subtractive processing, or the like.

Referring now to FIG. 7B, the piezoelectric regions 714 may be formed over the end regions of moveable beam 712. According to an embodiment, the piezoelectric regions 714 may be deposited in an amorphous phase. In order to improce the piezoelectric properties of the piezoelectric regions 714, the amorphous layer may be crystallized with a laser annealing process. For example, the piezoelectric regions 714 may be deposited with a sputtering process, a chemical solution deposition process, an ink jetting process, or the like. According to an embodiment, the piezoelectric regions 714 may be PZT, KNN, ZnO, or combinations thereof. In an embodiment, the laser annealing process may be a pulsed laser anneal and implemented so that the temperature of the substrate 705 does not exceed approximately 260° C. As such, embodiments of the invention allow for piezoelectric regions 714 to be formed on low temperature substrates, such as organic substrates. According to an embodiment, a pulsed laser annealing process used to crystallize the amorphous piezoelectric layer may use a laser source (e.g., an excimer laser) with an energy density in the range of approximately 10-100 mJ/cm² and pulse width in the range of approximately 10-50 nanoseconds.

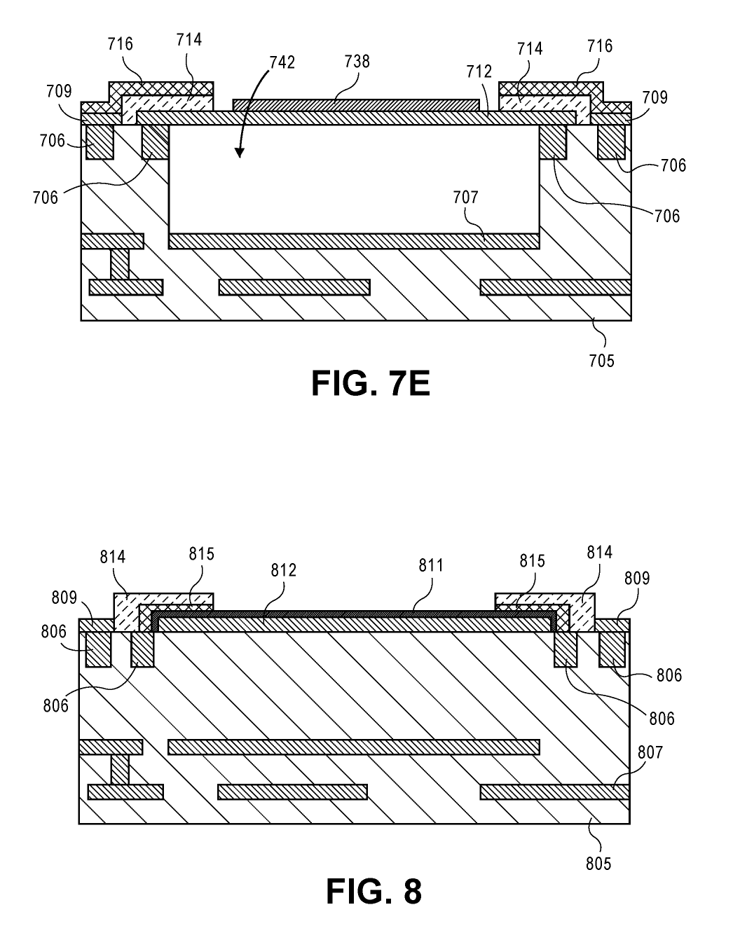

While FIG. 7B illustrates that the piezoelectric regions 714 are formed directly on the moveable beam 712, embodiments are not limited to such configurations. Referring briefly ahead to FIG. 8, an additional embodiment of the invention illustrates a processing procedure, where an electrically insulating layer 811 is formed directly over the moveable beam 812 (similar to the moveable beam 312 illustrated in FIG. 3). In such embodiments, an electrode 815 may be formed over the electrically insulating layer 811. The piezoelectric region 814 may then be formed over the electrode 815 in a manner substantially similar to the process described above with respect to FIG. 7B. After the piezoelectric region 814 is formed, the processing may proceed in substantially the same manner described with respect to FIGS. 7C-7E, in order to produce an OGS substantially similar to the one illustrated and described with respect to FIG. 3.

Returning back to the process flow in FIGS. 7A-7E, FIG. 7C illustrates electrodes 716 having been formed over the piezoelectric regions 714. According to an embodiment, the electrodes 716 may be formed with damascene processes or any other additive or subtractive processing operations. As illustrated, the electrodes 716 may be electrically coupled to conductive pads 709 on the substrate 705 that are electrically isolated from the conductive vias 706 that are connected to the moveable beam 712. Accordingly, a voltage may be applied across the piezoelectric regions 714 in order to displace the moveable beam 712 after the cavity is formed.

Referring now to FIG. 7D, a reflective surface 738 may be formed over the moveable beam 712. According to an embodiment, the reflective surface 738 may be formed by depositing and patterning a layer of reflective material (e.g., silver, aluminum, tin, gold, etc.). For example, the deposition process may be a sputtering, evaporation, or other suitable deposition process that is compatible with organic substrates. In some embodiments a protective coating (not shown) may also be deposited over the reflective surface 738 in order to prevent oxidation or other damage.

Referring now to FIG. 7E, the moveable beam 712 is released from the substrate 705 in order to allow for actuation. The moveable beam 712 may be released by forming a cavity 742 below a portion of the moveable beam 712. For example, the cavity 742 may be formed with a photolithography and etching process that selectively removes the portion of the substrate 705 below the moveable beam 712. For example, the etching process may be a reactive ion etching process, or any other wet or dry etching process. As illustrated, embodiments may use a trace 707 that is formed in the organic substrate 705 as an etchstop layer to provide the desired depth of the cavity 742.

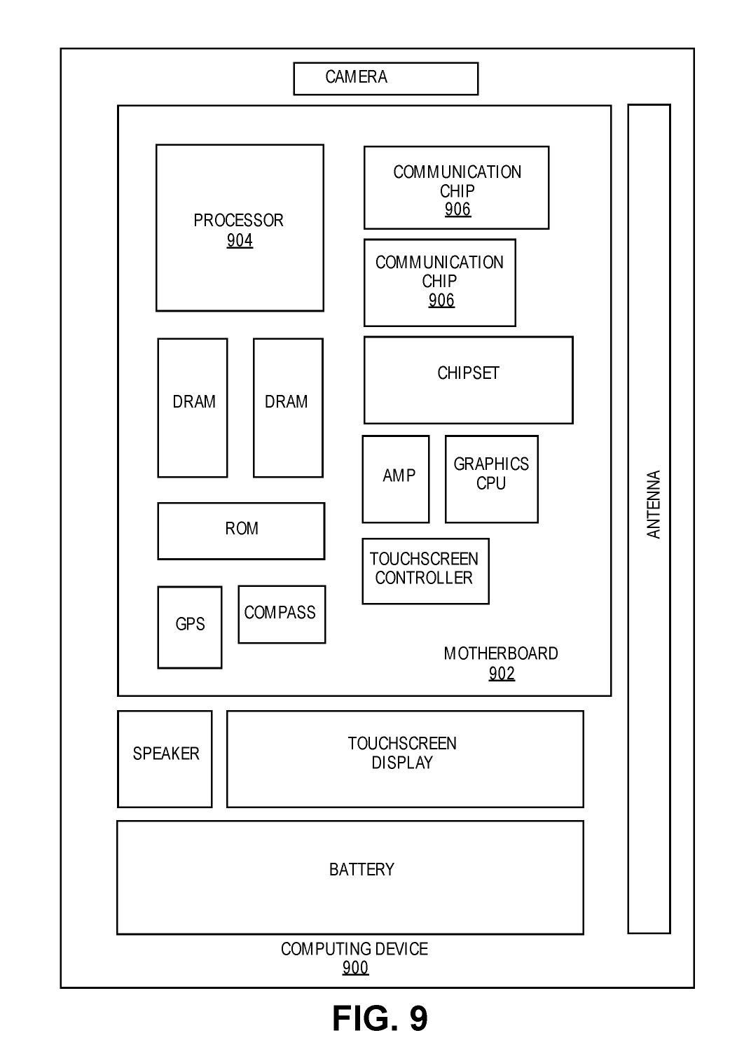

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be packaged on an organic substrate and provide a voltage to actuate moveable beams in a piezoelectrically driven OGS that is integrated into the organic substrate, in accordance with implementations of the invention. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be packaged on an organic substrate and provide a voltage to actuate moveable beams in a piezoelectrically driven OGS that is integrated into the organic substrate, in accordance with implementations of the invention.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Embodiments of the invention include a display system, comprising: an organic substrate;
an optical grating switch that comprises an array of moveable beams anchored to the organic substrate and suspended over a cavity formed in the organic substrate, wherein each of the moveable beams comprises: a piezoelectric region formed over end portions of the moveable beam; a top electrode formed over a top surface of each of the piezoelectric regions; and a reflective surface formed over a central portion of the moveable beam; and an integrated circuit die electrically coupled to the optical grating switch and configured to provide a voltage across each of the piezoelectric regions.

Additional embodiments of the invention include a display system, wherein the array of moveable beams includes four or more moveable beams.

Additional embodiments of the invention include a display system, wherein the optical grating switch further comprises: a plurality of static beams that are formed in an alternating pattern with the moveable beams, wherein the static beams are suspended over the cavity, and a reflective surface is formed over a central portion of the static beams.

Additional embodiments of the invention include a display system, further comprising a plurality of optical grating switches, and wherein the integrated circuit die is electrically coupled to each of the optical grating switches.

Additional embodiments of the invention include a display system, further comprising: a light source positioned so that light emitted by the light sources is directed to the optical grating switch.

Additional embodiments of the invention include a display system, wherein the light source is a color wheel.

Additional embodiments of the invention include a display system, further comprising: a spatial filter, wherein the spatial filter blocks light reflected by the optical grating switch from the zero order and allows light diffracted by the optical grating switch from the first order to pass through the spatial filter.

Additional embodiments of the invention include a display system, further comprising: a lens for focusing diffracted light from the optical grating switch that passes through the spatial filter onto a location on a screen.

Additional embodiments of the invention include a display system, further comprising: a scanner for moving the location across the screen.

Additional embodiments of the invention include a display system, wherein the scanner is rotatable in two directions.

Embodiments of the invention include an optical grating switch, comprising: a cavity formed into an organic substrate; and an array of moveable beams anchored to the organic substrate and suspended over the cavity, wherein each of the moveable beams comprises: a piezoelectric region formed over end portions of the moveable beam; a top electrode formed over a top surface of each of the piezoelectric regions; and a reflective surface formed over a central portion of the moveable beam.

Additional embodiments of the invention include an optical grating switch, wherein the top electrode of each moveable beam is electrically coupled to a conductive pad, and wherein each of the moveable beams is electrically coupled to a second conductive pad.

Additional embodiments of the invention include an optical grating switch, wherein alternating moveable beams in the array of moveable beams are displaced into the cavity towards the organic substrate when a voltage is applied across the piezoelectric regions of the alternating moveable beams.

Additional embodiments of the invention include an optical grating switch, wherein the displacement of alternating moveable beams forms a diffraction grating.

Additional embodiments of the invention include an optical grating switch, wherein the alternating moveable beams are displaced into the cavity approximately 200 nm or less.

Additional embodiments of the invention include an optical grating switch, wherein each moveable beam further comprises: an electrically insulating layer formed on a top surface of the moveable beam; and a bottom electrode formed over the electrically insulating layer, wherein the bottom electrode contacts the piezoelectric region.

Additional embodiments of the invention include an optical grating switch, wherein the bottom electrode and the top electrode are each coupled to a different conductive pad on the substrate, and wherein the moveable beam is not electrically coupled to the piezoelectric region.

Additional embodiments of the invention include an optical grating switch, wherein the array of moveable beams includes four or more moveable beams.

Additional embodiments of the invention include an optical grating switch, further comprising: an array of static beams that are formed in an alternating pattern with the array of moveable beams, wherein the static beams are suspended over the cavity, and a reflective surface is formed over a central portion of the static beams.

Additional embodiments of the invention include an optical grating switch, wherein applying a voltage across the plurality of piezoelectric regions of the moveable beams causes the moveable beams to displace into the cavity towards the organic substrate.

Additional embodiments of the invention include an optical grating switch, wherein the moveable beams are displaced approximately 200 nm or less.

Embodiments include a method of forming an optical grating switch, comprising: forming an array of beams over an organic substrate; depositing a piezoelectric material over end portions of the beams, wherein the piezoelectric layer has a substantially amorphous crystal structure; crystallizing the piezoelectric material with a pulsed laser anneal, wherein a temperature of the organic substrate does not exceed 260° C.; forming an electrode over a top surface of the piezoelectric material; forming a reflective surface over a center portion of each of the beams; and forming a cavity below a portion of the beam.

Additional embodiments of the invention include a method of forming an optical grating switch, wherein the pulsed laser anneal is performed with an Excimer laser with an energy density in the range of approximately 10-100 mJ/cm² and pulse width in the range of approximately 10-50 nanoseconds.

Additional embodiments of the invention include a method of forming an optical grating switch, wherein the piezoelectric layer is deposited with a sputtering or ink-jetting process.

Additional embodiments of the invention include a method of forming an optical grating switch, wherein the cavity is formed with a reactive ion etching process.

What is claimed is:

1. A display system, comprising:
an organic substrate;
an optical grating switch that comprises an array of moveable beams anchored to the organic substrate and suspended over a cavity formed in the organic substrate, wherein each of the moveable beams comprises:
a piezoelectric region formed over end portions of the moveable beam;
a top electrode formed over a top surface of each of the piezoelectric regions; and
a reflective surface formed over a central portion of the moveable beam; and
an integrated circuit die electrically coupled to the optical grating switch and configured to provide a voltage across each of the piezoelectric regions.

2. The display system of claim 1, wherein the array of moveable beams includes four or more moveable beams.

3. The display system of claim 1, wherein the optical grating switch further comprises:
a plurality of static beams that are formed in an alternating pattern with the moveable beams, wherein the static beams are suspended over the cavity, and a reflective surface is formed over a central portion of the static beams.

4. The display system of claim 1, further comprising a plurality of optical grating switches, and wherein the integrated circuit die is electrically coupled to each of the optical grating switches.

5. The display system of claim 1, further comprising:
a light source positioned so that light emitted by the light sources is directed to the optical grating switch.

6. The display system of claim 5, wherein the light source is a color wheel.

7. The display system of claim 5, further comprising:
a spatial filter, wherein the spatial filter blocks light reflected by the optical grating switch from the zero order and allows light diffracted by the optical grating switch from the first order to pass through the spatial filter.

8. The display system of claim 7, further comprising:
a lens for focusing diffracted light from the optical grating switch that passes through the spatial filter onto a location on a screen.

9. The display system of claim 8, further comprising:
a scanner for moving the location across the screen.

10. The display system of claim 9, wherein the scanner is rotatable in two directions.

11. An optical grating switch, comprising:
a cavity formed into an organic substrate; and
an array of moveable beams anchored to the organic substrate and suspended over the cavity, wherein each of the moveable beams comprises:
a piezoelectric region formed over end portions of the moveable beam;
a top electrode formed over a top surface of each of the piezoelectric regions; and
a reflective surface formed over a central portion of the moveable beam.

12. The optical grating switch of claim 11, wherein the top electrode of each moveable beam is electrically coupled to a conductive pad, and wherein each of the moveable beams is electrically coupled to a second conductive pad.

13. The optical grating switch of claim 12, wherein alternating moveable beams in the array of moveable beams are displaced into the cavity towards the organic substrate when a voltage is applied across the piezoelectric regions of the alternating moveable beams.

14. The optical grating switch of claim 13, wherein the displacement of alternating moveable beams forms a diffraction grating.

15. The optical grating switch of claim 13, wherein the alternating moveable beams are displaced into the cavity approximately 200 nm or less.

16. The optical grating switch of claim 11, wherein each moveable beam further comprises:
an electrically insulating layer formed on a top surface of the moveable beam; and
a bottom electrode formed over the electrically insulating layer, wherein the bottom electrode contacts the piezoelectric region.

17. The optical grating switch of claim 16, wherein the bottom electrode and the top electrode are each coupled to a different conductive pad on the substrate, and wherein the moveable beam is not electrically coupled to the piezoelectric region.

18. The optical grating switch of claim 11, wherein the array of moveable beams includes four or more moveable beams.

19. The optical grating switch of claim 11, further comprising:
an array of static beams that are formed in an alternating pattern with the array of moveable beams, wherein the static beams are suspended over the cavity, and a reflective surface is formed over a central portion of the static beams.

20. The optical grating switch of claim 19, wherein applying a voltage across the plurality of piezoelectric regions of the moveable beams causes the moveable beams to displace into the cavity towards the organic substrate.

21. The optical grating switch of claim 20, wherein the moveable beams are displaced approximately 200 nm or less.

22. A method of forming an optical grating switch, comprising:
forming an array of beams over an organic substrate;
depositing a piezoelectric material over end portions of the beams, wherein the piezoelectric layer has a substantially amorphous crystal structure;
crystallizing the piezoelectric material with a pulsed laser anneal, wherein a temperature of the organic substrate does not exceed 260° C.;
forming an electrode over a top surface of the piezoelectric material;
forming a reflective surface over a center portion of each of the beams; and
forming a cavity below a portion of the beam.

23. The method of claim 22, wherein the pulsed laser anneal is performed with an Excimer laser with an energy density in the range of approximately 10-100 mJ/cm² and pulse width in the range of approximately 10-50 nanoseconds.

24. The method of claim 22, wherein the piezoelectric layer is deposited with a sputtering, chemical solution deposition, or ink-jetting process.

25. The method of claim 22, wherein the cavity is formed with a reactive ion etching process.
